(19) United States
(12) Patent Application Publication
(10) Pub. No.: US 2013/0199025 A1
(43) Pub. Date: Aug. 8, 2013

(54) STABLE THERMOELECTRIC DEVICES

(71) Applicants: Dieter Platzek, Mulheim-Karlich (DE); Bo Brummerstedt Iversen, Skodstrup (DK); Mogens Christensen, Aarhus N (DK)

(72) Inventors: Dieter Platzek, Mulheim-Karlich (DE); Bo Brummerstedt Iversen, Skodstrup (DK); Mogens Christensen, Aarhus N (DK)

(73) Assignees: PANCO GMBH, Mülheim-Kärlich (DE); AARHUS UNIVERSITET, Aarhus C (DK)

(21) Appl. No.: 13/877,882

(22) PCT Filed: Oct. 5, 2011
(86) PCT No.: PCT/DK11/50377

§ 371 Date: Apr. 4, 2013

(30) Foreign Application Priority Data
Oct. 5, 2010 (EP) 10186591.3

(51) Int. Cl. H01L 35/34

(52) U.S. Cl. CPC H01L 35/34
USPC 29/592.1

(57) ABSTRACT

The present invention relates to a thermoelectric device 100A comprising a layered structure comprising a first layer 106, a first electrical connector 102, a second electrical connector 104, and a second layer 108 being different from the first layer 106, where the first layer comprises a material having the stoichiometric formula Zn4Sb3 (zinc antimonide)and the second layer 108 comprises Zn (zinc). The first layer 106 is being placed between the first and second electrical connector 102, 104, and the second layer 108 is placed between the first layer 106 and the first electrical connector 102. By having a second layer 108 comprising Zn the negative effects of electromigration of Zn may be overcome, since Zn may emanate from the foil and refill Zn depleted regions in the first layer. In a particular embodiment the second layer is a foil. In another particular embodiment, the first layer is doped with an element such as magnesium.

### FIELD OF THE INVENTION

The present invention relates to a thermoelectric device, in particular the present invention relates to a stable thermoelectric device, use of a stable thermoelectric device and a method of manufacture of a stable thermoelectric device.

### BACKGROUND OF THE INVENTION

Zn4Sb3 has been reported years ago as highly promising p-type material for thermoelectric applications in the technologically important midterm temperature range (200-400 degree Celsius).

Several attempts have successfully been done to get the material Zn4Sb3 itself temperature stable up to 400 degree Celsius by using measures aimed at preventing degradation of Zn4Sb3. The degradation of Zn4Sb3 can be divided into a plurality of processes:

Zn4Sb3->3 ZnSb+Zn 1)

Zn4Sb3->4 Zn+3 Sb 2)

and then

4 Zn+2O2->4 ZnO 3)

The extent of the above mentioned processes can be lowered significantly with addition of Zn, zone-refinement and sealing of the material against the ambient to avoid loss of Zn due to oxidation.

WO 2006/128467 A2 describes a thermoelectric material of the p-type having the stoichiometric formula Zn4Sb3, wherein part of the Zn atoms optionally being substituted by one or more elements selected from the group comprising Sn, Mg, Pb and the transition metals in a total amount of 20 mol % or less in relation to the Zn atoms is provided by a process involving zone-melting of an arrangement comprising an interphase between a “stoichiometric” material having the desired composition and a “non-stoichiometric” material having a composition deviating from the desired composition. The thermoelectric materials obtained exhibit excellent figure of merits.

However, even though the measures mentioned above are taken and excellent figure of merits are obtained, the Zn4Sb3 material may still suffer from lack of stability which can lead to less than optimal performance.

Hence, an improved thermoelectric device would be advantageous, and in particular a more stable, efficient and/or reliable thermoelectric device would be advantageous.

### SUMMARY OF THE INVENTION

In particular, it may be seen as an object of the present invention to provide a thermoelectric device that solves the above mentioned problems by being more stable, efficient and/or reliable. It is a further object of the present invention to provide an alternative to the prior art.

Thus, the above described object and several other objects are intended to be obtained in a first aspect of the invention by providing a thermoelectric device comprising a layered structure comprising
a first layer, the first layer comprising a material having the stoichiometric formula Zn4Sb3,
a first electrical connector,
a second electrical connector, and
a second layer being different from the first layer, the second layer comprising Zn,
   the first layer being placed between the first and second electrical connector, and the second layer being placed between the first layer and the first electrical connector, wherein the second layer has been adjoined to the first layer in a pressing step.

The invention is particularly, but not exclusively, advantageous for obtaining a thermoelectric device that solves the above mentioned problems by being more stable, efficient and/or reliable. In addition, the thermoelectric device according to the invention may be more mechanically stable, and/or remain mechanically stable during use, and/or increase mechanical stability during use. Another advantage is that the thermoelectric device according to the invention may be relatively cheap, such as cheap to manufacture, since the material cost for Zn4Sb3 is relatively low compared to other thermoelectrically active materials. Another advantage may be that the thermoelectric device according to the invention has an improved electrical contact resistance and electrical conductivity. The invention is based on the insight that stability, such as stability during preparation, such as long term stability during use, is undermined by electromigration of zinc (Zn), such as zinc ions, such as Zn2+ ions inside the Zn4Sb3 material. The invention provides a measure against negative effects of this electromigration. By stability is understood that a first parameter, such as Seebeck coefficient, such as electrical conductivity, remains constant, such as substantially constant, with respect to a second parameter, such as temperature, such as time. It is understood that the first parameter need not be exactly constant, but may also be termed stable if it is substantially constant although varying within a relatively small range, such as within 0.1%, such as within 1% such as within 10%, such as within a measurement uncertainty. A further insight forming a basis for the present invention is related to the issue of rendering the thermoelectrically active material electrically accessible. In order to get an operational thermoelectric device the thermoelectrically active material has to be contacted electrically, and during the process of realizing the electrical connection, the thermoelectrically active material may be degraded due to harmful thermal or mechanical influences, such process thus posing a risk that the thermoelectrical material has inferior mechanical or thermoelectrical properties. This may for example be the case if a high temperature process, such as soldering or brazing, is required in order to realize the connection. Furthermore, such process may demand considerable resources in terms of labour, machinery, time, energy and/or costs. The present invention may solve one or more of these problems by providing a thermoelectric device which comprises a thermoelectrically active material which is electrically connected to the electrical connectors by means of a pressing step.

It is understood that the first and second layer are a coherent structure, i.e., the first layer and the second layer are adjoined physically. In a particular embodiment, the second layer has not been melted, such as melted throughout its bulk structure, during the process of adjoining the second layer to the first layer. In another particular embodiment, the first layer has been adjoined to the second layer in a sintering step.

It should be noted that in the present application and in the appended claims, the term “a material having the stoichiometric formula Zn4Sb3” is to be interpreted as a material having a stoichiometry which traditionally and conventionally has been termed Zn4Sb3 and having a Zn4Sb3 crystal structure. However, it has recently been found that these materials having the Zn4Sb3 crystal structure contain interstitial zinc atoms making the exact stoichiometry Zn12.82Sb10, equivalent to the stoichiometry Zn3.846Sb3 (cf. Disordered zinc in Zn4Sb3 with Phonon Glas, Electron Crystal Thermoelectric Properties, Snyder, G. J.; Christensen, M.; Nishibori, E.; Rabiller, P.; Caillat, T.; Iversen, B. B., Nature Materials 2004, 3, 458-463; and Interstitial Zn atoms do the trick in Thermoelectric Zinc Antimonide, Zn4Sb3. A combined Maximum Entropy Method X-Ray Electron Density and an Ab Initio Electronic Structure Study, Caglioni, F.; Nishibori, 20 E.; Rabiller, P.; Bertini, L.; Christensen, M.; Snyder, G. J.; Gatti, C.; Iversen, B. B., Chem. Eur. J. 2004, 10, 3861-3870). In the present application and in the appended claims the optional substitution of one or more elements selected from the group comprising Sn, Mg, Pb and the transition metals in a total amount of 20 mol % or less in relation to the Zn atoms is based on the amount of Zn atoms of the exact stoichiometry Zn4Sb3. Accordingly, the stoichiometry of a material having the maximum degree of substitution of metal X is Zn3.2X0.8Sb3.

Hereinafter, “Zn4Sb3” is used interchangeably with “a material having the stoichiometric formula Zn4Sb3”.

Zn4Sb3 can become stable with respect to temperature changes, but for a thermoelectric application it must also be stable against electromigration of Zn inside the Zn4Sb3 material, where Zn ions are moving to the cathode in the case of current flow which is imperative in a thermoelectric device. Electromigration may disturb the equilibrium and lead to processes 1) and 2) as described in the background section. Electromigration of Zn ions, inside the thermoelectric material Zn4Sb3 may lead to Zn poor areas and Zn rich areas. The negative effects of electromigration thus include degradation of the thermoelectrically active material Zn4Sb3. The negative effects of electromigration may not be averted by addition of Zn, zone-refinement or sealing of the material against the ambient and electromigration is hence still problematic during manufacture and use, such as long term use, if no measures are taken against it.

By thermoelectric device is understood a device which is capable of creating a voltage when there is a different temperature on each side of the device. In practical thermoelectric devices, typically at least two thermoelectric legs are inserted, which legs are of different types.

By thermoelectric leg is understood a thermoelectrically active material. For application in thermoelectric devices, the thermoelectric legs have to be rendered electrically accessible. By thermoelectrically active material is understood a material wherein a voltage due to the Seebeck effect occurs when there is a corresponding temperature gradient.

Thermocouple is known in the art and describes a thermoelectric device which comprises a p-type thermoelectric leg and an n-type thermoelectric leg which are electrically connected so as to form an electric circuit. By applying a temperature gradient to this circuit an electric current will flow in the circuit making such a thermocouple a power source. Alternatively electric current may be applied to the circuit resulting in one side of the thermocouple being heated and the other side of the thermocouple being cooled. In such a set-up the circuit accordingly functions as a device which is able to create a temperature gradient by applying electrical power.

The physical principles involved in these above phenomena are the Seebeck effect and the Peltier effect respectively.

According to one embodiment of the invention, the thermoelectric device comprises a third layer being different from the first layer and comprising Zn, the third layer being arranged between the first layer and the second electrical connector. A possible advantage of this embodiment is that the layered structure need not be oriented in a particular direction with respect to the current. Specifically, the current may be directed from the first electrical connector to the second electrical connector, through the first layer, or vice versa. In any of the two cases, compounds comprising Zn, such as Zn ions, such as Zn2+ ions, may move, by means of electromigration, from either the second or third layer into the first layer. According to one embodiment of the invention, a the thickness of the second and or third layer in a direction of current through the corresponding layer when a voltage is applied between the first and second electrical connector, may be within 0.001 mm-10 mm, such as 0.001 mm-0.01 mm, such as 0.01 mm-0.1 mm, such as 0.1 mm-1 mm, such as 1-10 mm.

Hereinafter, it is generally understood that the group of compounds referred to by ‘compounds comprising Zn’ includes Zn ions, such as Zn2+ ions.

According to one other embodiment of the invention, a thermoelectric device is provided wherein the second layer and the first layer are arranged so as to allow electromigration of compounds comprising Zn from the second layer into the first layer. A possible advantage of this may be that during preparation and use, compounds comprising Zn from the second layer may, by means of electromigration, move into the first layer.

By ‘allowing electromigration’ is understood that compounds comprising Zn are allowed to spatially move, such as from the second layer into the first layer, as a result of an applied electric potential with a gradient in that direction. In a specific embodiment, this may be realized by having the first layer and second layer being connected by an intermediate electrical conductor of another material through which one or more compounds comprising Zn may electromigrate. In another specific embodiment, this is realized by having the first and second layer being in direct physical and electrical contact, such as touching each other.

According to one other embodiment of the invention, a thermoelectric device is provided wherein the second layer and the first layer are arranged so as to allow compounds comprising Zn electromigrating into the first layer to replace compounds comprising Zn which have electromigrated within the first layer. A possible advantage of this embodiment, is that compounds comprising Zn which have electromigrated within the first layer, may leave a Zn depleted region behind, which Zn depleted region may benefit from receiving compounds comprising Zn which originally were placed in the second layer.

By ‘to allow compounds comprising Zn electromigrating into the first layer to replace compounds comprising Zn which have electromigrated within the first layer’ is understood that the first and second layer are arranged ‘so as to allow electromigration of compounds comprising Zn from the second layer into the first layer’ (as described above) and furthermore that the compounds comprising Zn which were originally in the first layer is enabled to electromigrate so that it can be replaced. In a specific embodiment, this may be realized by having the first and second layer being connected by an intermediate electrical conductor of another material through which one or more compounds comprising Zn may electromigrate and wherein compounds comprising Zn can electromigrate within the first layer, such as within the bulk portion of the first layer, such as from one side of the first layer to the other side of the first layer.

According to one other embodiment of the invention, a thermoelectric device is provided wherein the second layer and the first layer are arranged so that the net flux of compounds comprising Zn through an interface between the first layer and the second layer, in a direction towards the first layer, is at least as large as the net flux of compounds comprising Zn through an imaginary surface within the first layer in the same direction. An advantage of this may be that the Zn content in a given region within the first layer is not diminished during preparation and use. In other words, a possible advantage is that the concentration of compounds comprising Zn within the first layer does not become lower over time, since the number of compounds comprising Zn within the first layer which electromigrates within the first layer is smaller than the number of compounds comprising Zn which is continuously supplied to the first layer by electromigration of compounds comprising Zn from the second layer to the first layer. Hence, effectively the “holes” resulting from compounds comprising Zn which are leaving their original position in the first layer, are continuously re-filled by compounds comprising Zn from the second layer, thus the amount of Zn in the first layer does not decline over time when a voltage is applied.

‘Flux’ is known in the art and corresponds to the amount of an entity traversing a surface, which surface may be imaginary, such as the amount of an entity traversing a surface per unit time.

By ‘flux of compounds’ is understood the amount of a compound traversing a surface, which surface may be imaginary.

By ‘compound’ may, in a particular embodiment, be understood a compound comprising Zn.

By ‘amount of compound’ may be understood the quantity of a compound, such as a number of compounds comprising Zn.

By a ‘net flux of compounds comprising Zn through an imaginary surface’ is understood the quantitative number of compounds comprising Zn which passes through a surface, such as per unit time, where it is taken into account that there may be a flux in both directions and the ‘net flux’ is the difference between the flux in the two directions.

In a particular embodiment the effect of having ‘the net flux of compounds comprising Zn through an interface between the first layer and the second layer, in a direction towards the first layer, is at least as large as the net flux of compounds comprising Zn through an imaginary surface within the first layer in the same direction’ may be realized by having a second layer wherein the concentration of Zn and a rate of electromigration (where rate of electromigration in is understood to correspond to ‘how far does a compound comprising Zn electromigrate per unit time’) within the second layer enables that the flux of compounds comprising Zn through the second layer, in a direction towards the first layer is at least as large as the corresponding net flux of compounds comprising Zn through an (imaginary) surface within the first layer in the same direction. In a particular embodiment, there may be provided a first element and a second element wherein, for a given voltage gradient, the product between concentration of compounds comprising Zn (being susceptible to electromigration) and the rate of electromigration within the second element is at least as large, such as larger, such as at least twice as large, such as at least 10 times larger, than the product between concentration of compounds comprising Zn (being susceptible to electromigration) and the rate of electromigration within the second element.

According to one other embodiment of the invention, a thermoelectric device is provided wherein at least one of the first electrical connector and second electrical connector comprises a conductor chosen from the group comprising: copper, silver, wolfram, molybdenum and zinc. In general, any conductor which has a low resistance may be used. Preferably, the first and second electrical conductors are capable of withstanding temperatures within the mid-temperature region, such as 200-400 degree Celsius. Preferably, the first and second electrical connectors are capable of withstanding temperature cycling within the mid-temperature region. Preferably, the first and second electrical connectors are not dissolving into the first layer during preparation or use. In case a first and second electrical connector may dissolve into the first layer, a diffusion barrier may be provided between each of the first and second electrical connector and the first layer, such as a Ni barrier in case of the first and second electrical connectors comprising copper. Wolfram is also known under the name tungsten.

According to one other embodiment of the invention, a thermoelectric device is provided wherein the first electrical connector comprises zinc and wherein the second layer and the first electrical connector is an integrated element. In another embodiment both the first electrical connector and the second electrical connector comprise zinc wherein the second layer and the first electrical connector is an integrated element and the third layer and the second electrical connector is an integrated element. A possible advantage of having the second or third layer and, respectively, the first and second electrical connector integrated, may be that it simplifies production, enabling faster and cheaper production, as well as other positive effects of integration of elements as will be readily understood by the skilled person. By ‘an integrated’ element is understood en element which physically represents one unit. In specific embodiments the integrated element may be realized, e.g., by a coherent zinc comprising element suitable for use an electrical connector, such as a monolithic zinc comprising element suitable for use an electrical connector, such as a homogeneous zinc comprising element suitable for use an electrical connector. By suitable for use as an electrical connector may be understood an element which has an electrical resistivity which is lower than the electrical resistivity of the first element.

According to one other embodiment of the invention, a thermoelectric device is provided wherein the first layer comprises Zn4Sb3 wherein part of the Zn atoms is substituted by one or more elements selected from the group comprising: Mg, Sn, Pb, the transition metals and the pnicogens in a total amount of 20 mol % or less in relation to the Zn atoms of Zn4Sb3. In other embodiments the percentage of the Zn atoms which are substituted by one or more elements selected from the group comprising: Mg, Sn, Pb, the transition metals and the pnicogens in relation to the Zn atoms of Zn4Sb3, may be less than 15 mol %, such as less than 10 mol %, may be less than 5 mol %, such as less than 4 mol %, may be less than 3 mol %, such as less than 2 mol %, may be less than 1 mol %, such as less than 0.1 mol %. Pnicogens are known in the art and understood to comprise group 15 elements of the periodic table including nitrogen (N), phosphorus (P), arsenic (As), Antimony (Sb), Bismuth (Bi).

The elements referred to as “transition elements” in the present description and the appended claims are to be understood as the group comprising the following elements: Sc, Ti, V, Cr, Mn, Fe, Co, Ni, Cu, Zn, Y, Zr, Nb, Mo, Ru, Rh, Pd, Ag, Cd, La, Hf, Ta, W, Re, Os, Ir, Pt, Au, Hg, and Ac.

It should be understood that in the present application, when the thermoelectric material according to the present invention has the stoichiometric formula Zn4Sb3 wherein part of the Zn atoms is substituted by one or more elements selected from the group comprising Sn, Mg, Pb and the transition metals, the amount of the total substitution may be 20% or less, such as 19% or less, e.g. 18% or less, for example 17% or less, or 16% or less, such as 15% or less, e.g. 14% or less, for example 13% or less, or 12% or less, such as 11% or less, e.g. 10% or less, for example 9% or less, or 8% or less, such as 7% or less, e.g. 6% or less, for example 5% or less, or 4% or less, such as 3% or less, e.g. 2% or less, for example 1% or less, or not more than 0.9%, 0.8%, 0.7%, 0.6%, 0.5%, 0.4%, 0.3%, 0.2% or 0.1%; all percentages being mol %.

According to one other embodiment of the invention, a thermoelectric device is provided wherein the first layer comprises compressed powder. An advantage of this may be that ingot due to the melting and crystallisation process is shrinking during the phase forming and is thus containing cracks. Using sintered powder may be advantageous in that it may overcome this problem. In one embodiment the powder is hand-milled powder.

According to one other embodiment of the invention, a thermoelectric device is provided wherein each of the first and second electrical connectors and the second layer are shaped to fit the shape of the first layer. A possible advantage of this may be that the layered structure does not take up more space than needed. This may be advantageous when packing a plurality of layered structures together, such as during storage, transportation or use. In an alternative embodiment, each of the first and second electrical connectors is shaped so as to at least cover the projected surface of first layer. An advantage of this may be that the current through the first layer becomes substantially homogeneous. In another alternative embodiment, the second layer is shaped so as to at least cover the projected interface of the first layer. An advantage of this may be that the flux of compounds comprising Zn moving, by means of electromigration, from the second layer and into the first layer becomes homogeneous, such as substantially homogeneous, through the interface between the first layer and the second layer.

According to one other embodiment of the invention, a thermoelectric device is provided wherein the second layer is a foil comprising Zn. By foil is understood a coherent layer, which in one dimension is small compared to the other two dimensions. The foil may be flexible. An advantage of using a foil may be that a relatively thin layer of material may be placed in the correct position during manufacture in a fast and uncomplicated manner during preparation. Another possible advantage may be that when using a foil, the second layer may obtain a well defined material composition, purity and thickness. In another possible embodiment the second layer is a solid element. In another possible element, the second layer is a powder which is compressed during preparation.

According to one other embodiment of the invention, a thermoelectric device is provided wherein the second layer comprises at least 99.0 wt % Zn, such as at least 99.9 wt % Zn. In other embodiments the second layer comprises at least 99.0 wt % Zn. In other embodiments the second layer comprises at least 1 wt % Zn, such as at least 5 wt % Zn, such as at least 10 wt % Zn, such as at least at least 25 wt % Zn, such as at least 50 wt % Zn, such as at least 75 wt % Zn, such as at least 80 wt % Zn, such as at least 85 wt % Zn, such at least 90 wt % Zn, such as at least 95 wt % Zn, such as at least 98 wt % Zn, such as at least 99.99 wt % Zn, such at least 99.999 wt % Zn, such as at least 99.9999 wt % Zn. It is noted that the purity, and/or the composition in general, may be examined by well-known analytical methods such as for example Energy-Dispersive X-ray analysis (EDX) or Potential-Seebeck-Microprobe (PSM).

In a particular embodiment the first layer is in the form of a pellet. The dimensions of pellets may range from 4 mm up to 18 mm diameter. In one embodiment, the thickness of the first layer, i.e., distance from one end of the first layer to the other end of the first layer in a direction from first electrical connector to the second electrical connector, is within a range of 0.1 mm to 10 mm, such as 0.1 mm, such as 0.5 mm, such as 1 mm, such as 1.5 mm, such as 2 mm, such as 5 mm, such as 10 mm, such as within a range of 1 mm to 5 mm. Other diameters, however, are also conceivable. It is also possible to cut the layered structure into many small legs, such as 1 mm×1 mm, such as 1 mm×1 mm×1 mm. Providing a plurality of appropriately sized thermoelectric legs may be advantageous for implementation in thermoelectric devices.

According to one other embodiment of the invention, the thermoelectric device comprises a plurality of layered structures. An advantage of this may be that the a thermoelectric device comprising a plurality of layered structures may be more beneficial in use, as it may be able to convert more thermal energy into electrical energy or it may be able to more efficiently generating a temperature difference when electrical power is applied.

In another embodiment according to the invention, the layered structure as described in any one of claims 1-13 is used as the p-type thermoelectric leg in a thermocouple. By devising these p-type thermoelectric legs in suitable sizes and arranging and connecting appropriately sized thermoelectric legs together with an n-type thermoelectric leg, a thermocouple is obtained in a way known per se. See for example “Frank Benhard; Technische Temperaturmessung; Springer Berlin, 2003; ISBN 3540626727”. In a special embodiment according to the present invention one or more thermocouples is/are arranged in a way known per se in order to obtain a thermoelectric device. See for example “Frank Benhard; Technische Temperaturmessung; Springer Berlin, 2003; ISBN 3540626727”.

According to a second aspect of the invention, the invention further relates to a method for manufacturing thermoelectric device according to any of the preceding claims, the method comprising
providing the first layer,
providing the first and second electrical connectors,
providing the second layer, and
   arranging the first layer between the first and second electrical connectors with the second layer being arranged between the first layer and the first electrical connector wherein the method further comprising
a pressing step wherein the second layer is adjoined to the first layer.

It is understood that the steps need not necessarily be carried out in the order in which they are given here, the pressing step may, for example, occur prior to providing the first and second electrical connectors.

A pressing step is understood by the skilled person to be a step wherein a force is applied to an area on each of the parts to be adjoined, wherein the force is large enough to make the parts adhere after the force, or pressure (corresponding to force per area), is removed. In a particular embodiment there is not applied sufficient energy so as to heat the interface between the first layer and the second layer, so as to melt bulk portions of the first layer and/or the second layer. In a particular embodiment there is also applied energy so as to heat the interface between the first layer and the second layer.

According to another embodiment, there is provided a method of manufacturing a thermoelectric device, the method further comprising
providing the third layer
arranging the third layer being between the first layer and the second electrical connector.

According to another embodiment, there is provided a method of manufacturing a thermoelectric device, wherein the first electrical connector is adjoined to the second layer in a pressing step.

According to another embodiment, there is provided a method of manufacturing a thermoelectric device, wherein the second electrical connector is adjoined to the third layer in a pressing step.

According to another embodiment, there is provided a method of manufacturing a thermoelectric device, wherein the second electrical connector is adjoined to the first layer in a pressing step. This may for example be relevant if there is not meant to be a third layer between the first layer and the second electrical conductor.

It is understood that there may be provided a plurality of pressing steps. For example, there may be provided a primary pressing step wherein the second layer is adjoined to the first layer, and subsequentially, in a secondary pressing step, the second layer and the first electrical connector are adjoined. It is also understood, that the above process may be carried out in a single pressing step wherein the first electrical connector is adjoined to the second layer and the first layer is adjoined to the second layer in the same pressing step, i.e., a sandwich structure comprising the first electrical connector, the second layer and the first layer—in that order—are adjoined in the single pressing step. It will be clear to the skilled person that different sequences of pressing steps may be employed to adjoin the first layer, second layer, third layer, first electrical connector, second electrical connector to the thermoelectric device shown in FIGS. 1A-B (with and without the third layer).

According to another embodiment, there is provided a method of manufacturing a thermoelectric device, wherein a sandwich structure comprising the first electrical connector, the second layer, the first layer, the third layer and the second electrical connector are adjoined in a pressing step. It is understood, that in a particularly advantageous embodiment, the first electrical connector, the second layer, the first layer, the third layer and the second electrical connector appear in that order, corresponding to the situation depicted in FIG. 1B. According to another embodiment, there is provided a method of manufacturing a thermoelectric device, wherein a sandwich structure comprising the first electrical connector, the second layer, the first layer and the second electrical connector are adjoined in a pressing step. It is understood, that in a particularly advantageous embodiment, the first electrical connector, the second layer, the first layer and the second electrical connector appear in that order, corresponding to the situation depicted in FIG. 1A.

According to another embodiment, there is provided a method of manufacturing a thermoelectric device, wherein the pressing step comprising applying a pressure of within 1 to 500 MPa, such as within 10 to 250 MPa, such as within 20 to 150 MPa, such as within 10 to 50 MPa, such as within 15-35 MPa, such as 25 MPa, such as within 25 to 100 MPa, such as within 30 to 90 MPa, such as within 35 to 80 MPa, such as within 40 to 70 MPa, such as within 45 to 60 MPa, such as 50 MPa.

According to another embodiment, there is provided a method of manufacturing a thermoelectric device, wherein the pressing step comprising having the first and/or second electrical connector at a temperature of within 50 to 700 degree Celsius, such as within 100 to 600 degree Celsius, such as within 200 to 500 degree Celsius, such as within 300 to 450 degree Celsius, such as within 350 to 400 degree Celsius, such as 350 degree Celsius, such as 385 degrees Celsius.

According to another embodiment, there is provided a method of manufacturing a thermoelectric device, wherein the pressing step comprising employing any one of a Hot Uniaxial Press or a Druck Sinter Presse or a Hot Isostatic Press.

According to another embodiment, there is provided a method of manufacturing a thermoelectric device, wherein the pressing step has a duration within 1-3600 minutes, such as within 1-1800 minutes, such as within 1-900 minutes, such as within 1-600 minutes, such as within 1-300 minutes, such as within 1-180 minutes, such as within 1-120 minutes, such as within 1-60 minutes, such as within 1-50 minutes, such as within 1-40 minutes, such as within 1-30 minutes, such as within 1-20 minutes, such as within 1-10 minutes, such as within 1-6 minutes, such as 6 minutes, such as within 10-180 minutes, such as within 15-180 minutes, such as within 20-180 minutes, such as within 25-180 minutes, such as within 25-60 minutes, such as within 25-45 minutes, such as within 25-35 minutes, such as 30 minutes.

According to another embodiment, there is provided a method of manufacturing a thermoelectric device, wherein the pressing step is a sintering step.

By ‘a sintering step’ is understood a step wherein two parts, such as the first layer and the second layer, are joined by heating the two parts to a temperature below the melting point of both of the two parts until its particles adhere to each other.

According to another embodiment, there is provided a method of manufacturing a thermoelectric device, wherein the first layer comprises powder before the pressing step and wherein the first layer is a solid and coherent element after the pressing step. This may for example be the case where the first layer is a powder, such as grinded or milled powder, before the pressing step, which powder is compressed into a solid and coherent element during the pressing step, such as the powder being compressed into a pellet. A possible advantage of this is that the process of forming a pellet, corresponding to the first layer, from the powder and the process of joining one or more of the first layer, the second layer, the third layer, the first electrical connector and/or the second electrical connector may be integrated into a single process step, such as a single pressing step.

A Zn4Sb3 ingot from quenching or zone refinement may not be directly suitable as thermoelectric leg, since due to the melting and crystallisation process the material may be shrinking during the phase forming and may thus contain cracks. So it may advantageously be further treated with grinding or milling to powder and then be pressed to a pellet, such as a bulky pellet, with Hot Uniaxial Pressing (HUP) or Spark Plasma Sintering (SPS) or ‘Druck Sinter Presse’ (DSP) (Eng. ‘sintering press’). To get an operational thermoelectric device the material has to be contacted electrically. This may be done by contacting the Zn4Sb3 pellet with Cu rods, such as Cu rods having a size so as to match the entire diameter of the Zn4Sb3 material, such as Zn4Sb3 pellet. During the pressing step a Zn-foil is placed between the Cu contact rods and Zn4Sb3 material. This Zn foil serves as a Zn reservoir, so that possibly lost Zn inside the Zn4Sb3 material is refilled.

In an embodiment, the first layer comprises Zn4Sb3 powder which is compressed during manufacture. The pressure during compression may vary, such as from 25 to 100 MPa. The temperature may vary, such as from 350 up to 400 degree Celsius. The period of time for the compression may vary from 3 min up to 1 hour. In a specific embodiment, the compression is given by a pressure of 100 MPa, a temperature of 400 degree Celsius and a time period of 1 hour. In another specific embodiment a Hot Uniaxial Press for HUP is used and the pressure applied is 100 MPa, the temperature is 385 degree Celsius and the time for pressing is 30 minutes. In another specific embodiment a DSP is used and the pressure applied is 25 MPa, the temperature is 350 degree Celsius and the time for pressing is 6 minutes. It is generally understood that there will be variations depending on the specific machine used.

In an embodiment, the method for manufacturing a thermoelectric device according to the first aspect is provided, wherein the step of providing the first layer comprises

i) mixing elements making op a composition of the first layer having to stoichiometric formula Zn₄Sb₃, wherein part of the Zn atoms optionally is substituted with one or more elements selected from the group comprising Mg, Sn, Mg, Pb and the transition metals in a total amount of 20 mol % or less in relation to the Zn atoms, and arranging the resultant mixture in an enclosure;

ii) evacuating and closing said enclosure resulting in an ampoule;

iii) heating said ampoule inside a furnace; and

iv) finally quenching the content of said ampoule by contacting said ampoule with water,

v) followed by grinding.

According to this embodiment of the invention, the material comprised within the first layer may be obtained by a simple thermal quench process in analogy with a method which may be referred to as the “quench method” (cf. Caillat et al., J. Phys. Chem. Solids, Vol. 58, No 7, pp. 1119-1125, 1997). The above mentioned method step is also described in the patent application WO 2006/128467 A2 which is hereby incorporated by reference in its entirety.

In a further embodiment, the method for manufacturing a thermoelectric device according to the first aspect comprises the step of mixing elements making op a composition of the first layer having the stoichiometric formula Zn₄Sb₃, wherein part of the Zn atoms optionally is substituted with one or more elements selected from the group comprising Mg, Sn, Mg, Pb and the transition metals in a total amount of 20 mol % or less in relation to the Zn atoms, and arranging the resultant mixture in an enclosure.

In yet another possible embodiment, the method for manufacturing a thermoelectric device according to the first aspect is provided, wherein the step of providing the first layer comprises zone-refinement. Zone-refinement in the present context is described in WO 2006/128467 A2 which is hereby incorporated by reference in its entirety.

It is noted that combining these methods, such as zone refinement and introduction of a second layer, may be advantageous in that it could impede a plurality of mechanisms of degradation, such as mechanisms relying on electromigration and oxidation respectively.

This aspect of the invention is particularly, but not exclusively, advantageous in that the method according to the present invention may be implemented by incorporating method steps known in the art, however, the distinguishing step or distinguishing steps may lead to improved properties of the thermoelectric device.

According to a third aspect of the invention, the invention relates to use of a thermoelectric device according to the first aspect of the invention for conversion of energy between thermal energy and electrical energy. The thermoelectric device may be applicable for such conversion in the technologically important midterm temperature range (200-400 degree Celsius), but may however also be applicable at other temperatures including 0-200 degree Celsius, or above 400 degree Celsius. The conversion of energy between thermal energy and electrical energy comprises conversion of thermal energy, such as heat, into electrical energy. This may be advantageous since in numerous devices, such as combustion engines, where a relatively large amount of energy is wasted in the form of heat. Converting this waste heat to electrical energy could be advantageous in terms of energy efficiency, money and in terms of the environment.

In another embodiment, the invention further relates to use of a thermoelectric device according to the first aspect of the invention for using electrical energy to heat an object at a first position and to cool down an object at a second position, such as for heating and cooling. This effect is known in the art as Peltier effect, and a device used for this purpose may in the art be known as a Peltier element. It is noted that a Peltier effect is possible also at elevated temperatures, such as within the mid-temperature range 200-400 degree Celsius. Use of a Peltier device may be particularly beneficial in applications where a temperature must be efficiently controlled or where a temperature difference is required without the introduction of mechanical or acoustic noise which may be a bi-product of other cooling devices.

The first, second and third aspect of the present invention may each be combined with any of the other aspects. These and other aspects of the invention will be apparent from and elucidated with reference to the embodiments described hereinafter.

### BRIEF DESCRIPTION OF THE FIGURES

The thermoelectric device according to the invention will now be described in more detail with regard to the accompanying figures. The figures show one way of implementing the present invention and is not to be construed as being limiting to other possible embodiments falling within the scope of the attached claim set.

FIG. 1 shows exploded view drawings of thermoelectric devices according to embodiments of the invention,

FIG. 2 shows in schematic form a thermoelectric device during and after a voltage is induced,

FIG. 3 shows in schematic form a thermoelectric device according to an embodiment of the invention during and after a voltage is induced,

FIG. 4 shows spatial distribution of Seebeck Coefficient for different samples after preparation,

FIG. 5 shows spatial distribution of Seebeck Coefficient for different doped samples after preparation,

FIG. 6 shows an experimental setup for long term testing,

FIG. 7 shows spatial distribution of Seebeck coefficient during long term testing at 200 deg Celsius,

FIG. 8 shows spatial distribution of Seebeck coefficient during long term testing at 285 deg Celsius,

FIG. 9 shows voltage-current characteristics and electrical conductivity as a function of current for Zn4Sb3 samples with and without first and second foil comprising zinc.

FIG. 10 shows voltage-current characteristics and electrical conductivity as a function of current for Zn4Sb3 samples with and without first and second foil comprising zinc, which Zn4Sb3 samples have been doped with Magnesium (Mg).

### DETAILED DESCRIPTION OF AN EMBODIMENT

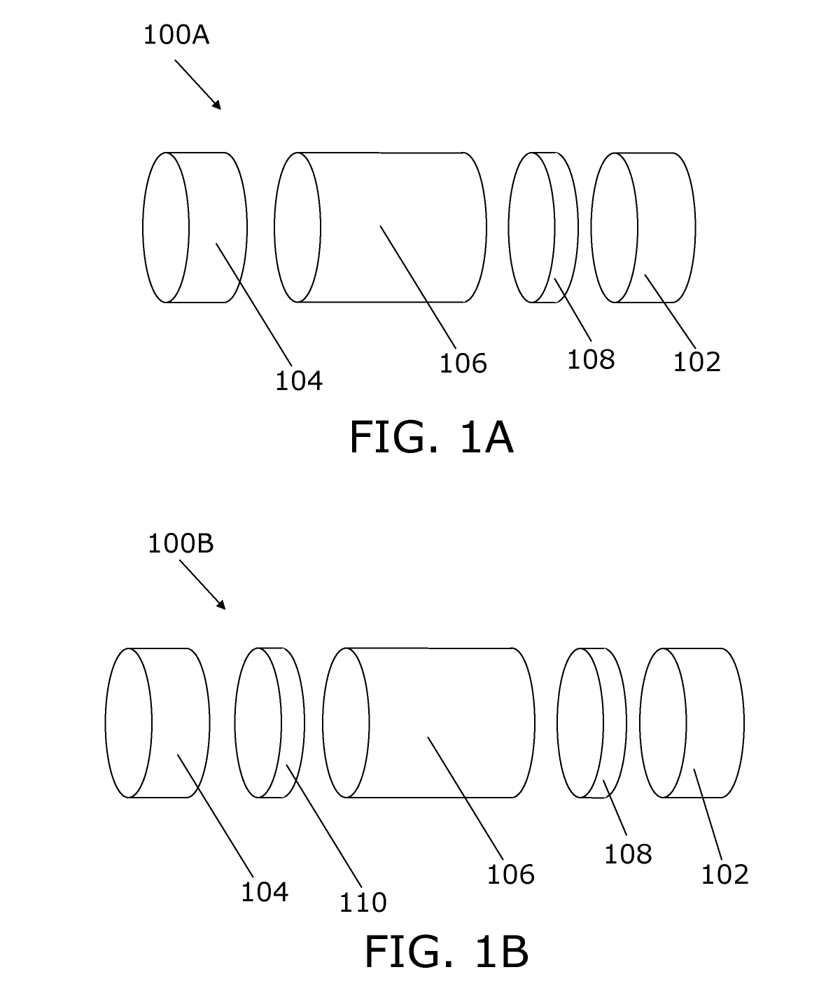

FIG. 1A shows an exploded view drawing of a thermoelectric device 100A according to an embodiment of the invention. The thermoelectric device 100A comprises a layered structure comprising a first electrical connector 102, a second electrical connector pad 104, a first layer 106 in the form of a Zn4Sb3 pellet, and a second layer 108, which second layer comprises zinc (Zn). In the shown embodiment, the second layer 108 is embodied by a foil comprising Zn.

FIG. 1B shows an exploded view drawing of another thermoelectric device 100B which is similar to the thermoelectric device shown in FIG. 1A, except that third layer 110 embodied by an other foil, which other foil comprises zinc (Zn), is placed between the second electrical connector 104 and the first layer 106 embodied by a Zn4Sb3 pellet.

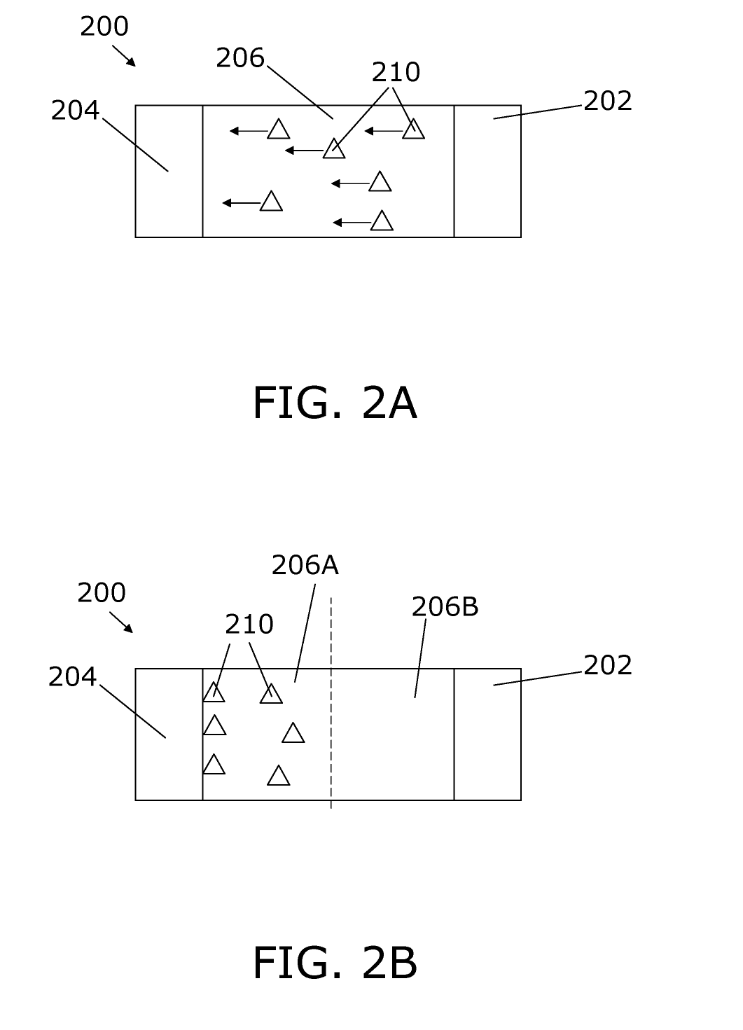

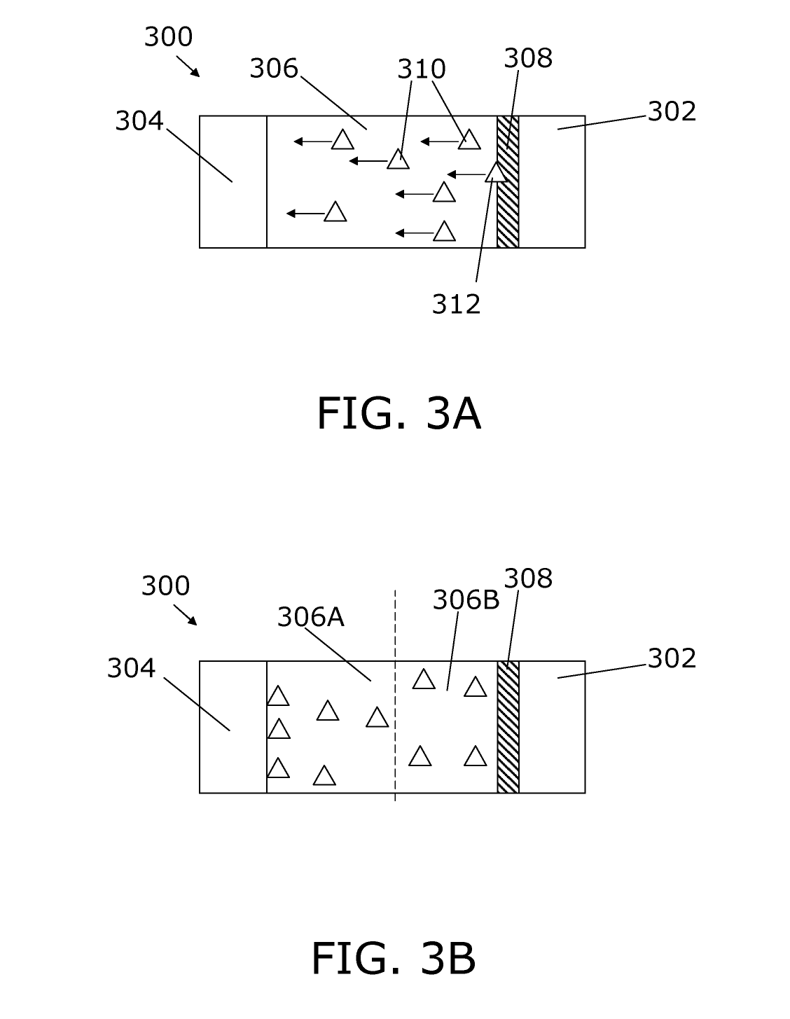

FIGS. 2-3 show schematics where speculations relating to the underlying principles are illustrated.

FIG. 2A shows a schematic showing a thermoelectric device 200 during a period where a voltage is induced. The figure shows first electrical connector 202, second electrical connector 204, and first layer 206 embodied by a layer of Zn4Sb3. Furthermore shown are Zn2+ ions, depicted as triangles 210. In the situation shown, a non-zero voltage is induced across the first layer 206 and the first electrical connector 202 acts as anode whereas the second electrical connector 204 acts as cathode. In the present context, anode is used as generally understood in the art, and defined as an electrical connector where oxidation takes place. Similarly, ‘cathode’ is used as generally understood in the art and defined as an electrical connector where reduction takes place. The Zn2+ ions 210 are shown moving, by means of electromigration, from the anode towards the cathode.

FIG. 2B shows the same thermoelectric device 200 as in FIG. 2A in a situation after a voltage has been induced across the first layer 206A-B for a period of time. Due to the electromigration of the Zn2+ ions, the first layer now has both a Zn rich region 206A and a Zn poor region 206B. The Zn poor regions may be termed depletion zones.

FIG. 3A shows a schematic showing a thermoelectric device 300, according to an embodiment of the invention, during a period where voltage is induced. The figure shows first electrical connector 302, second electrical connector 304, second layer 308 comprising Zn, and first layer 306 being a Zn4Sb3 element. Furthermore shown are Zn2+ ions, depicted as triangles 310. In the situation shown a non-zero voltage is induced across the Zn4Sb3 element 306 and the first electrical connector 302 acts as anode whereas the second electrical connector 304 acts as cathode. The Zn2+ ions 310 are shown moving, by means of electromigration, from the anode towards the cathode. Furthermore shown, is a Zn2+ ion 312 which emanates from the second layer 308 and which also moves, by means of electromigration, from the anode towards the cathode.

FIG. 3B shows the same thermoelectric device 300 as in FIG. 3A in a situation after a voltage has been induced across the Zn4Sb3 element for a period of time. Due to the electromigration of the Zn2+ ions, the Zn2+ ions originally located within the first layer 306 now has been relocated. However, due to the Zn2+ ions emanating from the second layer 308 during the period where a non-zero voltage is applied, there are substantially no depletion zones where the Zn content has dropped substantially.

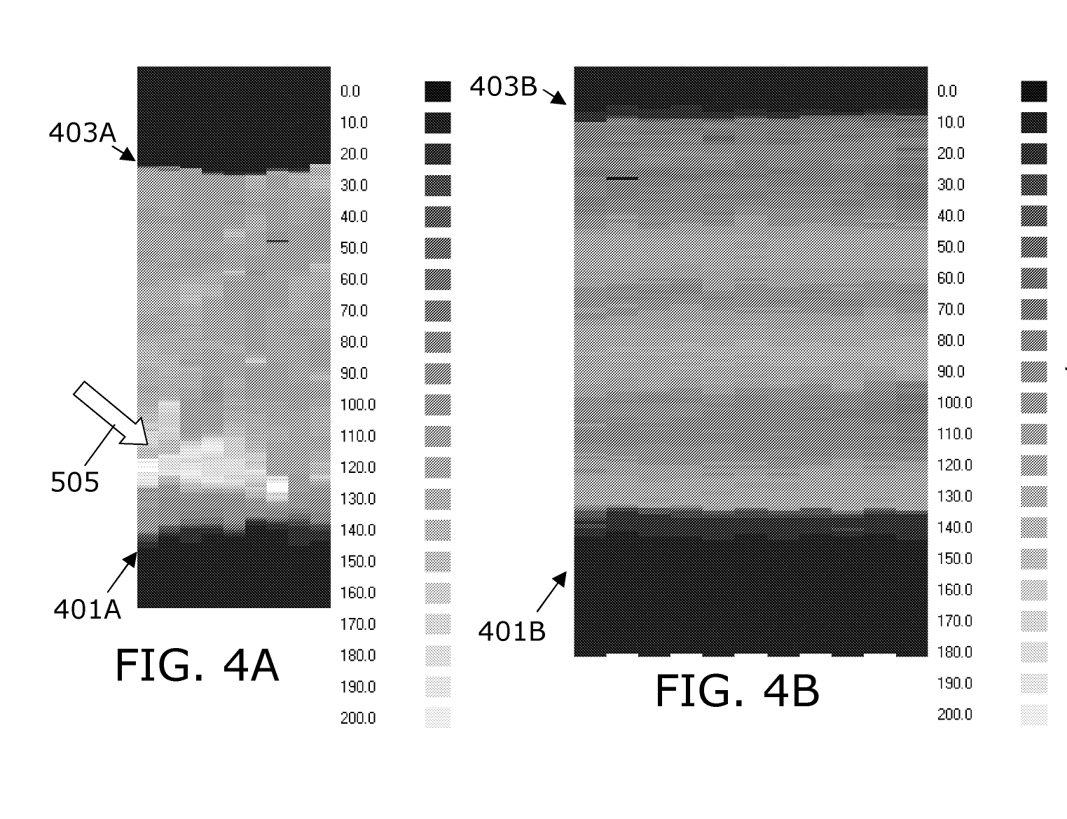

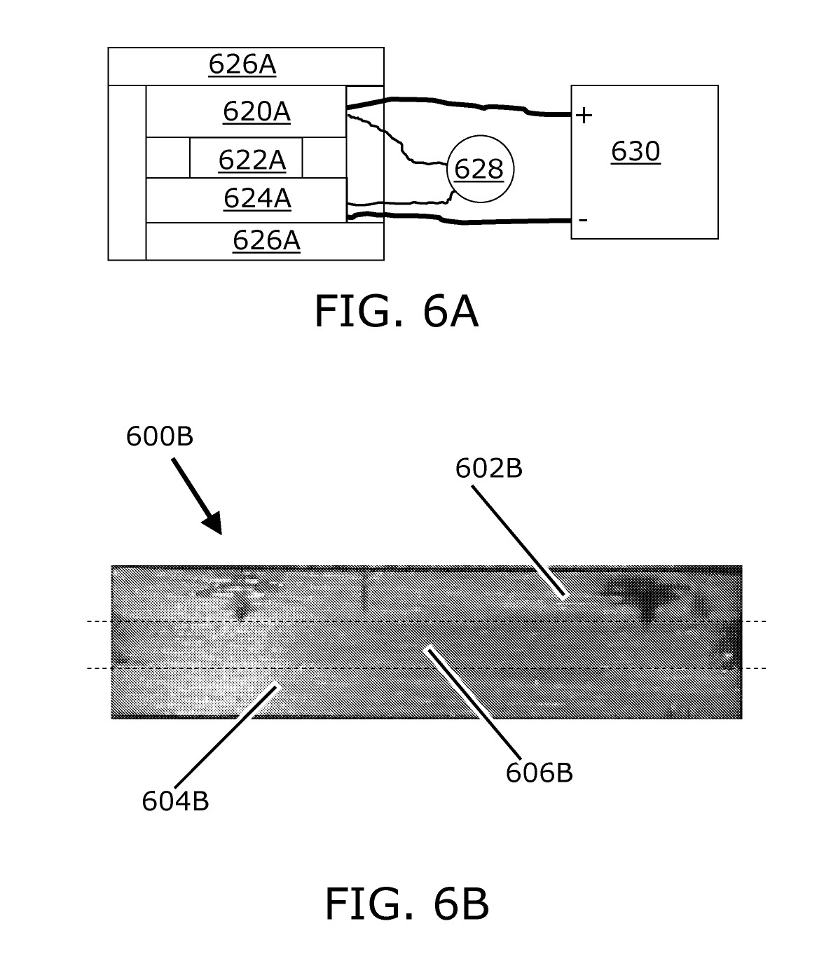

FIGS. 4-5 and FIGS. 7-8 show spatial distribution of Seebeck Coefficient for different thermoelectric legs in different situations. In each scan, three layers are visible in. Two black layers corresponding to first and second electrical connector, which are here Cu electrodes (see also FIG. 6B), and in the middle the first layer comprising Zn4Sb3. In some scans, a second layer and/or a third layer comprising zinc, such as a Zn foil, is present and placed, respectively, between the first or second electrical connector and the first layer, but this is not visible in the scans.

In FIGS. 4-5 and FIGS. 7-10 the first layer comprises Zn4Sb3 thermoelectric material, with or without 1 mol % Mg doping. The protocol for preparing this material includes thermal quenching in analogy to the prior art quench method, which is described in WO2006/128467A2 which is hereby included as reference in its entirety. In particular, reference is made to examples 1 and 2 in WO2006/128467A2.

FIG. 4 shows spatial distribution of Seebeck Coefficient for different thermoelectric legs after preparation. What can be seen in the false colour diagram is a cut-through sectional view through the centre of a first layer, in the form of a Zn4Sb3 pellet, where the first and second electrical connectors, in the form of copper (Cu) rods, are placed along the upper- and lower side of the first layer, respectively. In FIG. 4A-B, the electrical connector functioning as anode is placed along the bottom side 401A-B, respectively, and the electrical connector functioning as cathode is placed along the upper side 403A-B, respectively. The surface of the interface was grinded before performing the scans for obtaining the Seebeck Coefficients. The preparation of the pellet comprises placing first layer between Cu plates in a pressing die, perform a sintering press. Or in other words, the preparation of the pellet comprises placing first layer between Cu plates in a pressing die, and performing a sintering press. Specific condition may be given by a temperature of 350 degree Celsius, a pressure of 25 MPa or 50 MPa, and the period for pressing given by 6 minutes. During preparation a current of the order of 1 kilo ampere is passed through the first layer from one Cu plate to the other Cu plate. A Seebeck Microprobe is used for measuring the spatial resolution of the Seebeck coefficient S in the sample which is a measure for the homogeneity or phase purity. The Seebeck Microprobe is well known in the art and described in “Potential-Seebeck-Microprobe PSM: Measuring the Spatial Resolution of the Seebeck Coefficient and the Electric Potential” by D. Platzek, G. Karpinski, C. Stiewe, P. Ziolkowski, C. Drasar, and E. Mueller, Proceeding of the 24th International Conference on Thermoelectrics ICT, Clemson (USA) 2005, p. 13, which is hereby incorporated by reference in its entirety. Potential-Seebeck-Microprobe (PSM) is interchangeably referred to as Seebeck Microprobe.

FIG. 4A shows the degradation of Zn4Sb3 in a thermoelectric device without a second layer comprising Zn inserted between the Cu plate acting as anode and the Zn4Sb3 pellet, after treating with a current of kilo ampere at 350 degree Celsius during pressing. The Seebeck-coefficient changes from the for Zn4Sb3 typical 100 microvolt/Kelvin range to the value range of 300 microvolt/Kelvin typical for ZnSb. Regions with relatively high Seebeck coefficients, such as the region indicated by the arrow, may be taken as a sign degradation already during preparation. The scale in FIG. 4A and FIG. 4B spans 0-200 microvolt/Kelvin.

FIG. 4B shows the spatial distribution of the Seebeck coefficient S of a thermoelectric device with a second layer, comprising Zn inserted between the Cu plate acting as anode and the Zn4Sb3 pellet, which thermoelectric device has been shown treated under the same conditions as the thermoelectric device shown in FIG. 4A. Only Seebeck coefficients around the values typical for Zn4Sb3, i.e., around 100 microvolt/Kelvin range, can be observed.

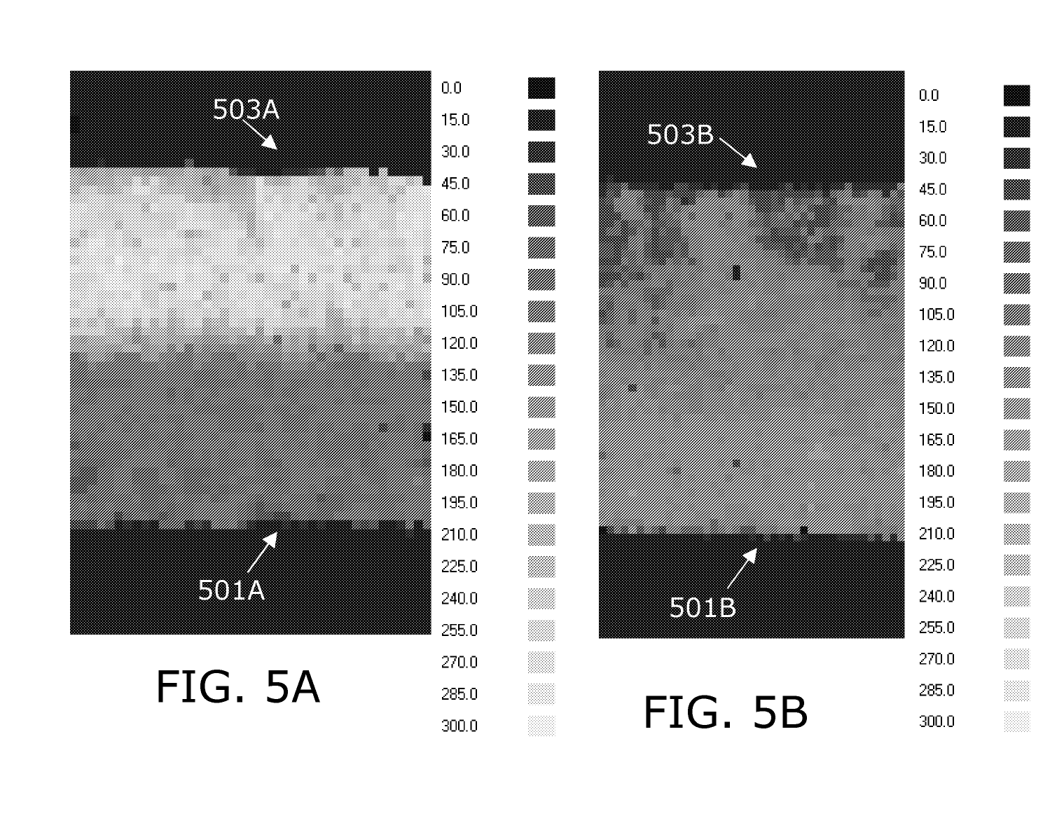

FIG. 5 shows spatial distribution of Seebeck Coefficient for different thermoelectric devices after preparation, as in FIG. 4, except that the Zn4Sb3 material in FIG. 5 have been doped with Magnesium (Mg) in a total amount of 1 mol % in relation to the Zn atoms of Zn4Sb3, i.e. corresponding to Mg0.04, Zn3.96, Sb3. FIG. 5A reveals degradation already during preparation in the thermoelectric device without the second layer inserted between anode and Zn4Sb3 pellet, which can be observed where the upper half of the pellet shows relatively high Seebeck coefficient values, e.g., as indicated by the thick arrow 505. No degradation can be observed in FIG. 5B where the thermoelectric device comprises a second layer comprising Zn inserted between the first electrical connector embodied by a Cu plate acting as anode and the first layer in the form of a Zn4Sb3 pellet. In FIG. 5A-B, the electrical connector functioning as anode is placed along the bottom side 501A-B, respectively, and the electrical connector functioning as cathode is placed along the upper side 503A-B, respectively. In FIGS. 5A-B, the scale spans 0-300 microvolt/Kelvin. In the examples of FIG. 4B and FIG. 5B, the second layer is embodied by a foil comprising 99.9 wt % Zn. In this case the foil had a thickness of 100 micrometer. If the thickness of the first layer is lower, e.g., in the range of 100 micrometer it may be advantageous to keep the foil in the range of, e.g., 10 micrometer.

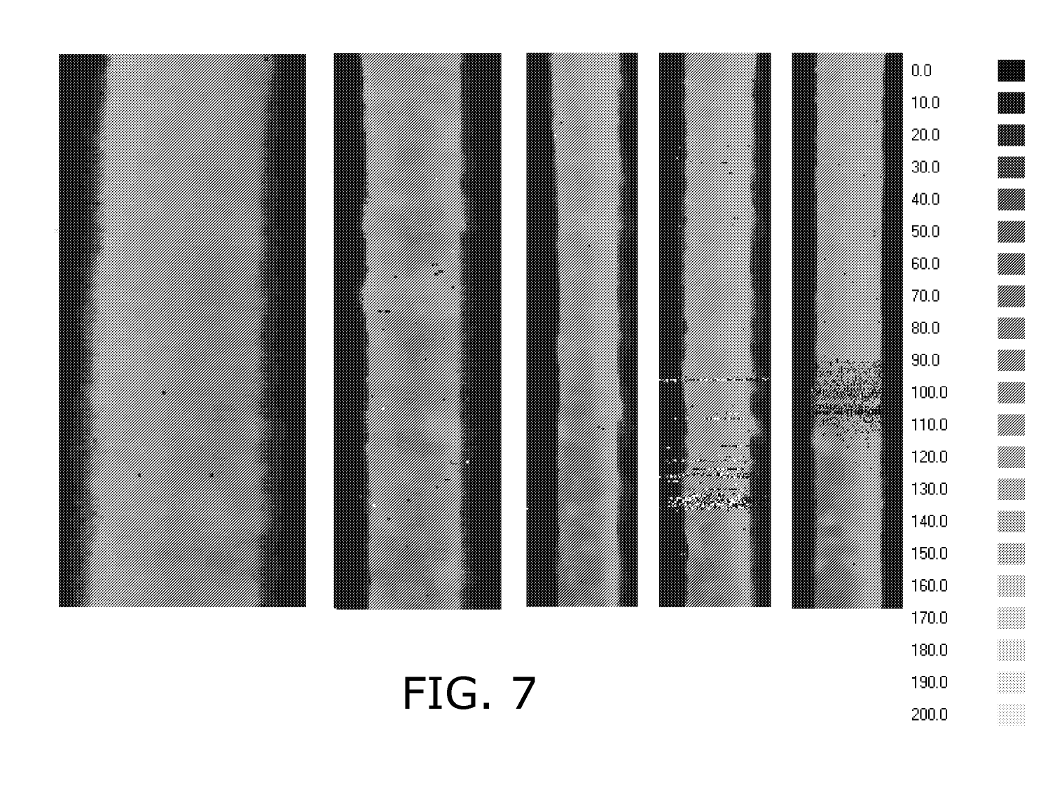

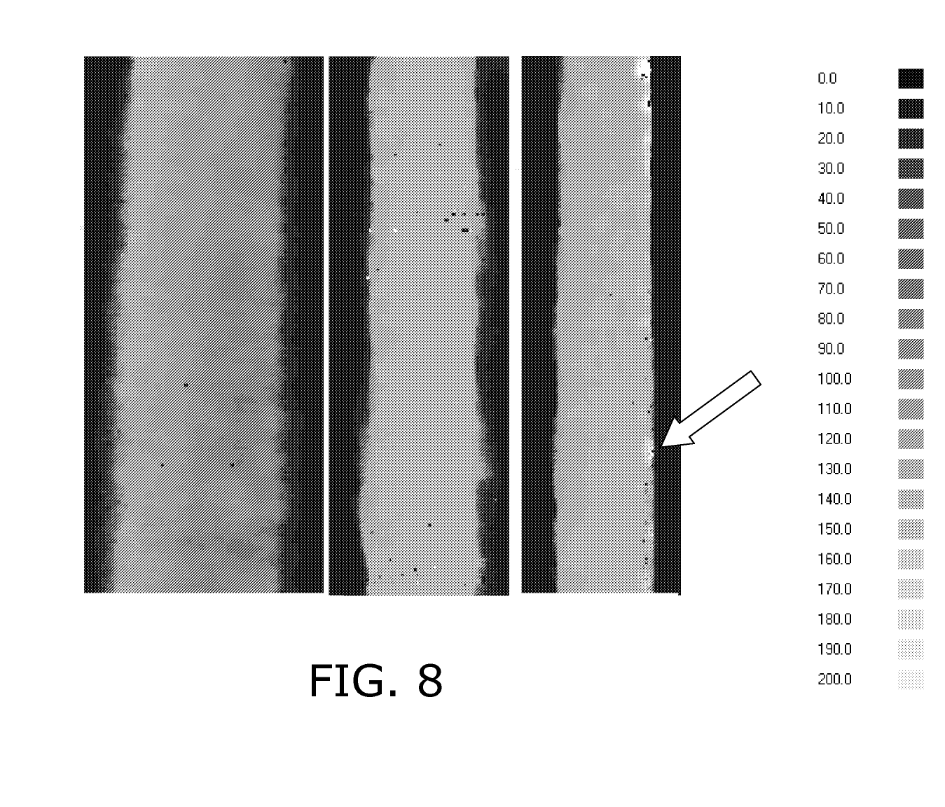

FIG. 6A shows an experimental setup for long term testing, which setup comprises a heater and contact block 620A, a sample 622A, a contact block 624A, and thermal- and electrical insulation 626A. The heater and contact block 620A and the contact block 624A are connected electrically both via a measurement probe 628 for measuring voltage-current (U/I) characteristics, and via a current source 630. During the long term tests the current source 628 delivers a DC current of 10 ampere. The long term tests are conducted in ambient air, and the samples are not sealed. In the present configuration, with the “+” wire leading to the heater and contact block 620A, and the “−” wire leading to the contact block 624A, the cathode side will be the same side as the side of the contact block 624A and the anode side will be the same as the side of the heater and contact block 620A. Results from the long term tests are shown in FIGS. 7-8.

FIG. 6B is a photograph showing a thermoelectric device 600B comprising a layered structure comprising a first layer 606B, being a Zn4Sb3 pellet, and first and second electrical connectors 602B, 604B embodied by Cu electrodes.

FIG. 7 shows spatial distribution of Seebeck coefficient during long term testing at 200 deg Celsius of a sample doped with Magnesium (Mg) in a total amount of 1 mol % in relation to the Zn atoms of Zn4Sb3, i.e. corresponding to Mg0.04, Zn3.96, Sb3. The scans from left to right are measured after respectively 0, 500, 800, 1000 and 1500 minutes where the sample was exposed to a current of 10 ampere flowing through the sample and where the sample was held at 200 deg Celsius in ambient atmosphere, i.e., exposed to atmospheric air. It is observed that no substantial degradation occurs. In FIG. 7 the orientation is so that the electrical connector functioning as anode is placed along the right hand side and the electrical connector functioning as cathode is placed along the left hand side.

The left- and right hand side are the long edges. In FIG. 7, the scale spans 0-200 microvolt/Kelvin.

FIG. 8 shows spatial distribution of Seebeck coefficient during long term testing at 285 deg Celsius of a sample doped with Magnesium (Mg) in a total amount of 1 mol % in relation to the Zn atoms of Zn4Sb3, i.e. corresponding to Mg0.04, Zn3.96, Sb3. The scans from left to right are measured after respectively 0, 200, 500 minutes where the sample was exposed to a current of 10 ampere flowing through the sample and where the sample was held at 285 deg Celsius in ambient atmosphere, i.e., exposed to atmospheric air. It is observed that no substantial degradation occurs. After 500 minutes small regions exhibiting relatively high Seebeck coefficients can be seen as indicated by the arrow. This may be interpreted as onset of degradation. As in FIG. 7, the orientation is so that the electrical connector functioning as anode is placed along the right hand side and the electrical connector functioning as cathode is placed along the left hand side. The left- and right hand side are the long edges. In FIG. 8, the scale spans 0-200 microvolt/Kelvin. The pixeling in FIG. 7 is somewhat noise, particularly in the scans corresponding to 1000 and 1500 minutes. This is interpreted as experimental, noise leading to erroneous measurement points, i.e., the noise values are not related to particularly high or low Seebeck coefficients.

In FIGS. 7-8 both a second layer and a third layer is present, where both second- and third layer is embodied by a foil of 99.9 wt % Zn. Thus, a foil comprising Zn is placed between both electrical connectors, i.e., anode and cathode, and the first layer being a pellet of compressed Zn4Sb3 powder. The first and second electrical connectors are embodied by Cu rods. In an alternative embodiment, the first and second electrical connectors may also be embodied by compressed material, which compressed material is highly conductive and capable of withstanding the temperatures of preparation and use.

In a particular embodiment, the first and/or second connectors are made by compressed powder, such as Cu powder. In another particular embodiment, the first and/or second connector are realized by having powder, such as Cu powder, placed adjacent to the first layer or the second layer or the third layer and performing a pressing step, such as a sintering step, so as to both compress the powder into a solid element, being the first and/or second connector, and adjoining the first and/or second connector to the first, second and/or third layer.

An estimate of the Mean Time Between Failures (MTBT) may be given, by calculating the ampere-hour (Ah) and relating this to a relevant current. In the given case, the inner resistance was measured by observing a voltage of 0.6 V at 10 A corresponding to 0.06 Ohm. The average Seebeck coefficient is approximately 150 microvolt/Kelvin. A temperature difference of 200 Kelvin thus corresponds to 30 mV. In use as a thermoelectric device, a load resistance with the same magnitude as the inner resistance of the thermoelectric leg is coupled in series with the thermoelectric leg. The current through the leg during practical use consequently amounts to 30 mV/K/(2*0.06 Ohm)=0.25 A. As a result, the MTBF can be estimated by equating the ampere hour (Ah) for the conditions during test and use, and obtain

MTBT=1500 minutes*10 A/0.25 A=60000 minutes=1000 hours

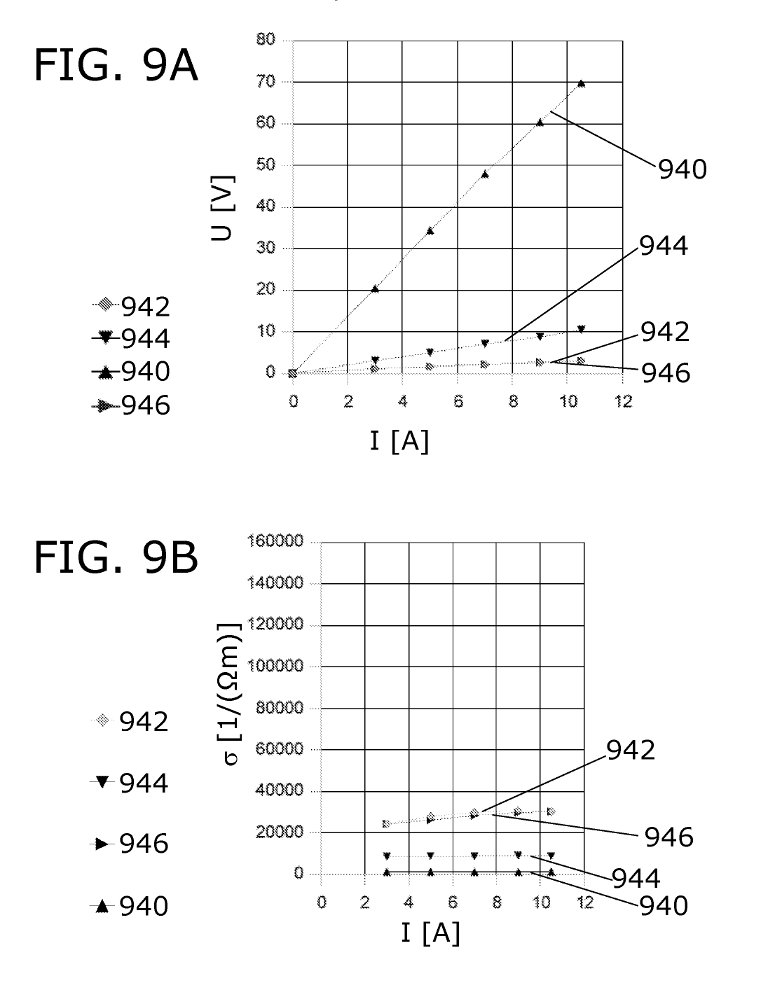

FIG. 9A-B shows respectively voltage-current characteristics (U[V] vs. I[A]) and electrical conductivity (sigma[1/(Omega meter)] vs. I[A]) as a function of current for Zn4Sb3 pellets without second or third layer 940, with second layer placed between the first layer and the first electrical connector where the first electrical connector is functioning as anode 942, with second layer placed between the first layer and the first electrical connector where the first electrical connector is functioning as cathode 944 and both second and third layer comprising zinc 946.

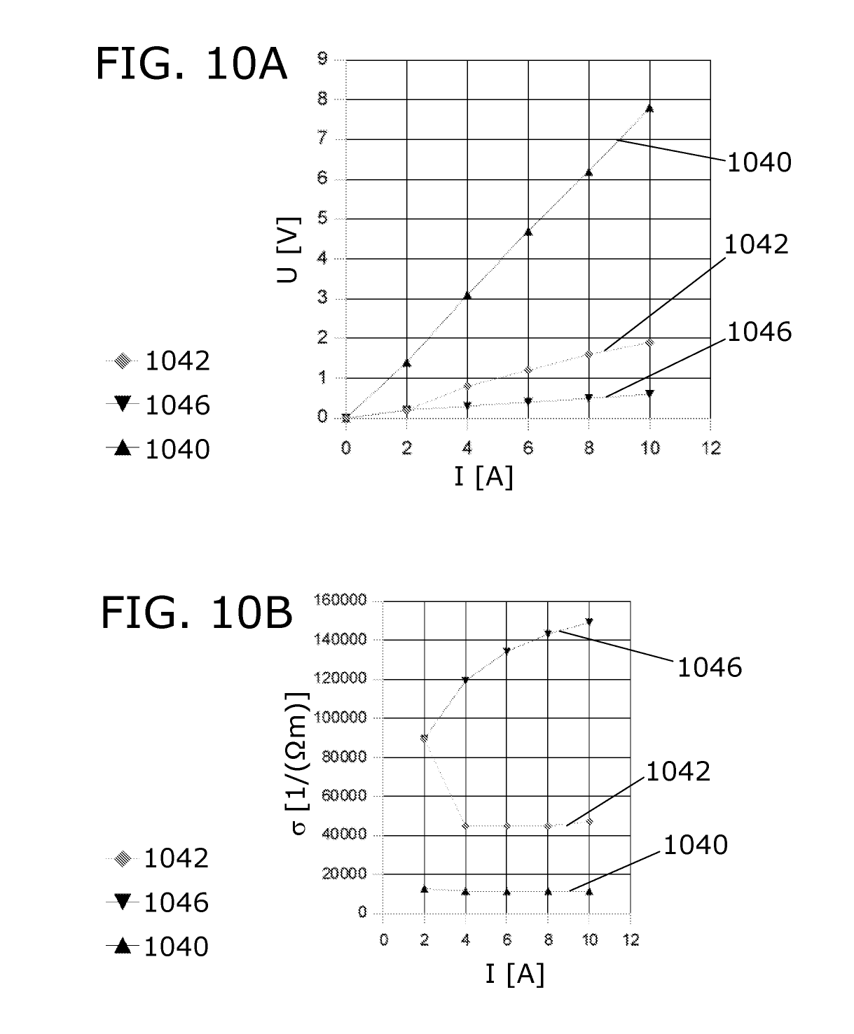

FIG. 10A-B similar kinds of datasets as in FIG. 9, however, FIG. 10 shows datasets measured on Zn4Sb3 pellets which have been doped with Magnesium (Mg) in a total amount of 1 mol % in relation to the Zn atoms of Zn4Sb3, i.e. corresponding to Mg0.04, Zn3.96, Sb3. Thus FIG. 10A-B shows in a similar manner to FIG. 9 respectively voltage-current (U[V] vs. I[A]) and electrical conductivity (sigma[1/(Omega meter)] vs. I[A]) as a function of current for Mg doped Zn4Sb3 pellets without second or third layer 1040, with second layer placed between the first layer and the first electrical connector where the first electrical connector is functioning as anode 1042 and both second and third layer comprising zinc 1046. It is noted that the measuring point corresponding to a current of 2 ampere for the curves denoted with reference signs 1042 and 1046 may be erroneous in FIGS. 10A-B.

In FIGS. 9-10, each second or third layer is embodied by a foil of 99.9 wt % Zn. It can be seen from FIGS. 9-10 that the electrical conductivity is significantly increased compared to samples without Zn foil. Furthermore, mechanical stability of the complete thermoelectric leg including first and second electrical connectors is significantly increased compared to samples without the second layer, such as a Zn foil. The increased mechanical stability of the thermoelectrical legs comprising a second layer, such as a foil comprising Zn, is evident as those thermoelectric legs are less prone to fracturing compared to thermoelectric legs without the second layer. Without the increased mechanical stability, the thermoelectrical legs may fracture during simple handling, whereas the increased mechanical stability may ensure that samples can withstand simple handling, such as moving and general handling by hand.

In an exemplary embodiments, there is provided a thermoelectric device (100A) comprising a layered structure comprising
a first layer (106), the first layer comprising a material having the stoichiometric formula Zn4Sb3,
a first electrical connector (102),
a second electrical connector (104), and
a second layer (108) being different from the first layer (106), the second layer comprising Zn,
   the first layer being placed between the first and second electrical connector, and the second layer being placed between the first layer and the first electrical connector.

In another exemplary embodiments, there is provided a method of manufacturing a thermoelectric device according to any of the preceding claims, the method comprising
providing the first layer,
providing the first and second electrical connectors,
providing the second layer, and
arranging the first layer between the first and second electrical connectors with the second layer being arranged between the first layer and the first electrical connector.

To sum up, the present invention relates to a thermoelectric device comprising a layered structure comprising a first layer, a first electrical connector, a second electrical connector, and a second layer being different from the first layer, where the first layer comprises a material having the stoichiometric formula Zn4Sb3 (zinc antimonide) and the second layer comprises Zn (zinc). The first layer is being placed between the first and second electrical connector, and the second layer is placed between the first layer and the first electrical connector. By having a second layer comprising Zn the negative effects of electromigration of Zn may be overcome, since Zn may emanate from the foil and refill Zn depleted regions in the first layer. In a particular embodiment the second layer is a foil. In another particular embodiment, the first layer is doped with an element such as magnesium.

Although the present invention has been described in connection with the specified embodiments, it should not be construed as being in any way limited to the presented examples. The scope of the present invention is set out by the accompanying claim set. In the context of the claims, the terms “comprising” or “comprises” do not exclude other possible elements or steps. Also, the mentioning of references such as “a” or “an” etc. should not be construed as excluding a plurality. The use of reference signs in the claims with respect to elements indicated in the figures shall also not be construed as limiting the scope of the invention. Furthermore, individual features mentioned in different claims, may possibly be advantageously combined, and the mentioning of these features in different claims does not exclude that a combination of features is not possible and advantageous.

1. A method of manufacturing a thermoelectric device comprising a layered structure comprising:
a first layer, the first layer comprising a material having the stoichiometric formula Zn4Sb3,
a first electrical connector,
a second electrical connector, and
a second layer being different from the first layer, the second layer comprising Zn,
wherein the method is comprising
providing the first layer in the form of a pellet,
providing the first and second electrical connectors,
providing the second layer, and
wherein the method is further comprising preparation of the pellet which comprises
placing the first layer between the first and second electrical connectors in a pressing die, with the second layer inserted between the first electrical connector and the pellet, and
performing a sintering press.

2-22. (canceled)

23. The method of manufacturing a thermoelectric device according to claim 1, the method further comprising:
providing a third layer that is different from the first layer, wherein said third layer comprises Zn;
arranging the third layer between the first layer and the second electrical connector; and
performing a pressing step such that the third layer is adjoined to the first layer.

24. The method of manufacturing a thermoelectric device according to claim 1, wherein the first electrical connector is adjoined to the second layer in a pressing step.

25. The method of manufacturing a thermoelectric device according to claim 23, wherein the second electrical connector is adjoined to the third layer in a pressing step.

26. The method of manufacturing a thermoelectric device according to claim 23, wherein a sandwich structure comprising the first electrical connector, the second layer, the first layer, the third layer and the second electrical connector are adjoined in the pressing step.

27. The method according to claim 1, wherein the sintering press comprises applying a pressure of within 1 to 500 MPa.

28. The method according to claim 1, wherein the sintering press comprises having the first and/or second electrical connector at a temperature of within 50 to 700 degrees Celsius.

29. The method according to claim 1, wherein the sintering press comprises employing a Hot Uniaxial Press, a Druck Sinter Presse, or a Hot Isostatic Press.

30. The method according to claim 1, wherein the sintering press has a duration within 1-3600 minutes.

31. The method according to claim 23, wherein the pressing step is also a sintering step.

32. The method according to claim 1, wherein the first layer comprises powder before the sintering press and, wherein the first layer is a solid and coherent element after the sintering press.

33. The method according to claim 1, wherein the second layer and the first layer are connected by an intermediate electrical conductor of another material through which one or more compounds comprising Zn may electromigrate or the first and second layer are in direct physical and electrical contact, so as to allow electromigration of compounds comprising Zn from the second layer into the first layer.

34. The method according to claim 1, wherein the second layer and the first layer are connected by an intermediate electrical conductor of another material through which one or more compounds comprising Zn may electromigrate or the first and second layer are in direct physical and electrical contact, so as to allow compounds comprising Zn to electromigrate into the first layer so as to replace compounds comprising Zn, which have electromigrated within the first layer.

35. The method according to claim 1, wherein the second layer and the first layer are connected by an intermediate electrical conductor of another material through which one or more compounds comprising Zn may electromigrate or the first and second layer are in direct physical and electrical contact, and wherein there is provided a first layer and a second layer wherein, for a given voltage gradient, the product between concentration of compounds comprising Zn are susceptible to electromigration and the rate of electromigration within the second layer is at least as large as the product between concentration of compounds comprising Zn are susceptible to electromigration and the rate of electromigration within the first layer, so that the quantitative number of compounds comprising Zn, which passes through an interface between the first layer and the second layer, in a direction towards the first layer, is at least as large as the amount of compounds comprising Zn traversing a surface, which passes through an imaginary surface within the first layer, in the same direction.

36. The method according to claim 1, wherein the first electrical connector comprises zinc and, wherein the second layer and the first electrical connector is an integrated element.

37. The method according to claim 1, wherein the first layer comprises Zn₄Sb₃ wherein part of the Zn atoms is substituted by one or more elements selected from the group consisting of: Mg, Sn, Pb, the transition metals, and the group 15 elements of the periodic table in a total amount of 20 mol % or less in relation to the Zn atoms of Zn₄Sb₃.

38. The method according to claim 1, wherein the first layer comprises compressed powder.

39. The method according to claim 1, wherein the second layer is a foil comprising Zn.

40. The method according to claim 1, wherein the second layer comprises at least 99.0 wt % Zn.

41. The method according to claim 1, wherein a plurality of layered structures as defined in any of the preceding claims is provided.
